(19) United States
(12) Patent Application Publication
(10) Pub. No.: US 2008/0025000 A1
(43) Pub. Date: Jan. 31, 2008

(54) ATCA LOCKING LEVER MOUNTING ARRANGEMENT

(75) Inventors: Yi-Tun Huang, Hsinchu City (TW); Feng-Qing Su, Shan-Hua Town (TW)

Correspondence Address: ADLINK TECHNOLOGY INC., P.O. BOX 108-00403, TAIPEI, omitted

(73) Assignee: ADLINK TECHNOLOGY INC., Chungho City (TW)

(21) Appl. No.: 11/459,936

(22) Filed: Jul. 26, 2006

(51) Int. Cl. H05K 7/16

(52) U.S. Cl. 361/726

(57) ABSTRACT

An ATCA locking lever mounting arrangement includes a motherboard blade, which has a face panel with a through hole and a grounding plate with two retaining spring arms, and a locking lever, which is pivoted to a motherboard blade for locking the motherboard blade to the machine case of a server system, having a retaining member for insertion through the through hole of the face panel into engagement with the retaining spring arms of the grounding plate and a protruded bearing portion and an actuating portion at two distal ends for stopping at the outside wall or inside wall of the machine case of the server system to limit the turning angle of the locking lever.

### BACKGROUND OF THE INVENTION

1. Field of the Invention

The present invention relates to an ATCA locking mounting arrangement for enabling a motherboard blade to be locked to a machine case of a server system and electrically connected to the server system quickly without any tools and more particularly, to a locking lever for the arrangement, which is easy to operate and safe in use and, which positively locks the motherboard blade to the machine case of the server system.

2. Description of the Related Art

Currently, many enterprises install relatively cheaper mini servers to satisfy network traffic requirements. In order to improve further economic effect, blade servers are developed. A blade server is essentially a housing for a number of individual minimally-packaged computer motherboard “blades”, each including one or more processors, computer memory, computer storage, and computer network connections, but sharing the common power supply and air-cooling resources of the chassis. The idea is that by placing many blades in a single chassis, and then 19-inch rack-mounting them, systems can be more compact and powerful, but less expensive than traditional systems based on mainframes, or server farms of individual computers.

The machine case of a blade server can accommodate several tens of motherboard blades or more. One single motherboard blade is equivalent to a server. The motherboard blades of a server system use a common machine case, a commonly display, a common keyboard, a commonly power adapter, and other resources. Further, a blade server system has an intelligent system mounted inside the machine case to separate motherboard blade resources, specific works, or application programs running in the motherboard blades, allowing free use of the motherboard blades in the machine case of the blade server system. A blade server system as the following benefits:
1. High extendability and reliability because the machine case supports hot plug of motherboard blades and related component parts.
2. Low power consumption with a common cooler device.
3. Simple outer appearance design.
4. System resources, specific application programs and works are separated.
5. Low cost.

The most attractive advantage of a blade server is its high reliability and extendibility. Every blade server has the backup function. The hot plugging of the server machine case that supports blade servers and system component parts provides high applicability. When one individual blade server failed, another blade server can take the place without interrupting the service of the system. When wishing to increase the processing power of the system, it needs only to insert more blade servers and to arrange these resources at the place where the demand is heavy.

Because blade servers provide the function of hot plugging function, plug and unplugging actions will be frequently seen in blade servers. The machine case of a blade server has an accommodation chamber and parallel rails arranged at different elevations in the accommodation chamber so that motherboard blades can be inserted into the accommodation chamber along the rails. After insertion of motherboard blades into the accommodation chamber of the machine case, the screws at each motherboard blade are respectively threaded into associating screw holes at the two opposite side panels of the machine case to fix each motherboard blade to the machine case. A motherboard blade generally has a locking lever provided at one side of the board. As shown in FIG. 8, the locking lever A is pivotally connected to one side of the face panel B1 of the motherboard blade B with a screw bolt A2. After insertion of the motherboard blade B in the machine case C of a server system, the locking lever A is biased to force a locking rod A1 of the locking lever A into engage a part C1 of the machine case C, and simultaneously to force an actuating portion A11 into contact with a sensor switch B2, causing the sensor switch B2 to switch on power supply of the motherboard blade B. This locking lever mounting design has drawbacks as follows:
1. The locking lever A has a retaining member A3 for engaging a through hole B11 on the face panel B1 to secure the locking lever A in the locking position. However, the retaining member A3 tends to be forced out of the through hole B11 of the face panel B1 accidentally upon a vibration.
2. Because the actuating portion A11 of the locking lever A has a big area, a big motherboard blade space around the sensor switch B2 must be kept empty for movement of the actuating portion A11. Therefore, the surface area of the motherboard blade B cannot be fully utilized.

Therefore, it is desirable to provide an ATCA locking lever mounting arrangement that eliminates the aforesaid problem.

### SUMMARY OF THE INVENTION

The present invention has been accomplished under the circumstances in view. According to one aspect of the present invention, two locking levers are respectively pivotally provided at two sides of a motherboard blade. After insertion of the motherboard blade into a machine case of a server system, the locking levers are turned to the locking position to lock the motherboard blade to the machine case of the server system and to simultaneously switch on a sensor switch, thereby connecting the motherboard blade to the server system electrically. Each locking lever has a protruding bearing portion and a retaining member. When turning each locking lever from the unlocking position to the locking position, the respective retaining member will be forced through a through hole on the face panel of the motherboard blade into engagement with retaining spring arms of a grounding plate of the motherboard blade, and the respective bearing portion will be stopped at the outside wall of the face panel, holding the respective locking lever positively in position.

According to another aspect of the present invention, the locking lever has an actuating portion with a contact face that triggers a sensor switch to switch on power supply of the motherboard blade after the locking lever has been turned to the locking position. The contact face has a relatively smaller diameter than the actuating portion. Therefore, the locking lever requires less space area around the sensor switch, and the surface area of the motherboard blade can be fully utilized.

According to still another aspect of the present invention, one end of the contact face of the actuating portion will be stopped at the inside wall of the face panel to limit the turning angle of the locking lever when turning the locking lever from the locking position to the unlocking position, preventing damage to the sensor switch accidentally.

### BRIEF DESCRIPTION OF THE DRAWINGS

FIG. 1 is an elevational view of an ATCA locking lever mounting arrangement according to the present invention.

FIG. 2 is an elevational view of the locking lever according to the present invention.

FIG. 3 is a schematic top view of the present invention showing the locking lever turned outwards from the unlocking position toward the locking position.

FIG. 4 is similar to FIG. 3, but showing the locking rod of the locking lever inserted into the retaining hole of the machine case.

FIG. 5 is a schematic top view of the present invention, showing the locking lever in the locking position.

FIG. 6 is a schematic top view of the present invention, showing the locking lever in the locking position.

FIG. 7 is an applied view of the present invention, showing a motherboard blade inserted into a machine case and two locking levers provided at two sides of the motherboard board.

FIG. 8 is a schematic drawing of a prior art design.

### DETAILED DESCRIPTION OF THE PREFERRED EMBODIMENT

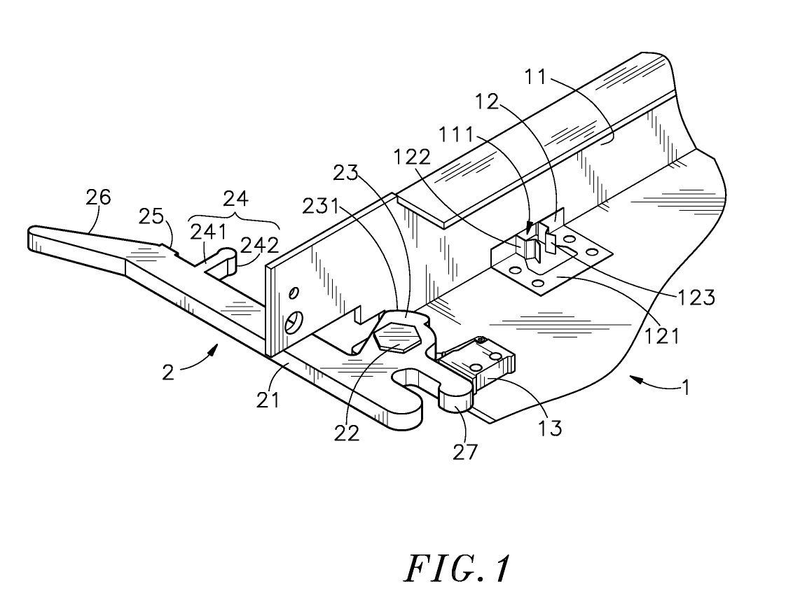

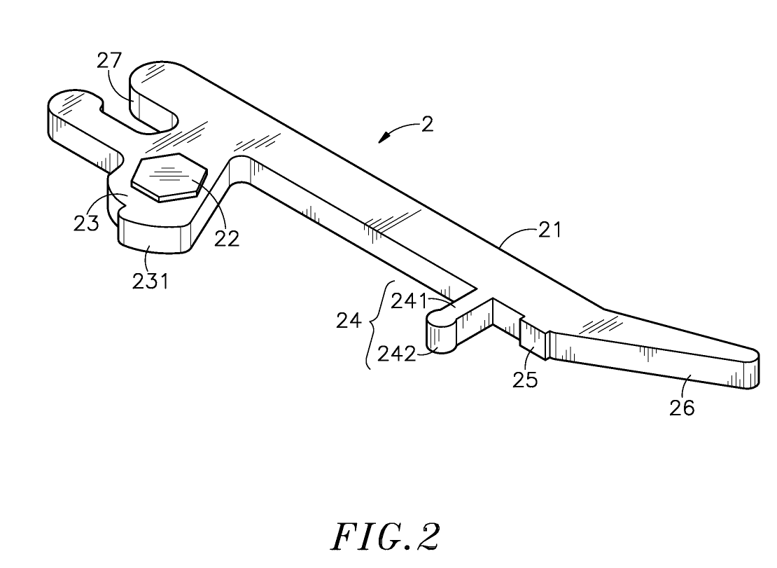

Referring to FIGS. 1˜3, an ATCA locking lever mounting arrangement in accordance with the present invention is shown comprising a motherboard blade 1 and a locking lever 2.

The motherboard blade 1 holds a motherboard (not shown), and has a face panel 11 at one side. The face panel 11 has a through hole 111, and a grounding plate 12 corresponding to the through hole 111. The grounding plate 12 has a flat base 121, two flanges 122 protruded from the flat base 121 at two opposite lateral sides of the through hole 111, and two retaining spring arms 123 respectively extending from the flanges 122. Further, a sensor switch 13 is installed in the motherboard at the motherboard blade 1.

The locking lever 2 comprises a narrow elongated flat lever body 21, a locking rod 27 extended from one end of the lever body 21, a grip 26 extended from the other end of the lever body 21, a protruded bearing portion 25 at one side of the connection area between the lever body 21 and the grip 26, a pivot 22 disposed adjacent to the locking rod 27 and pivoted to the motherboard blade 1, an actuating portion 23 suspending around the pivot 22, the actuating portion 23 having a contact face 231 for touching the sensor switch 13, and a retaining member 24 extended from one side of the lever body 21 adjacent to the bearing portion 25. The retaining member 24 has a head 242, and a neck 241 connected between the head 242 and the lever body 21. The contact face 231 has an outer diameter relatively smaller than the actuating portion 23.

During installation, the pivot 22 of the locking lever 2 is pivoted to the motherboard blade 1, keeping the grip 26 suspending outside the motherboard blade 1 so that a user can grasp the grip 26 to turn the locking lever 2 relative to the motherboard blade 1 between the locking position and the unlocking position (this will be described further.

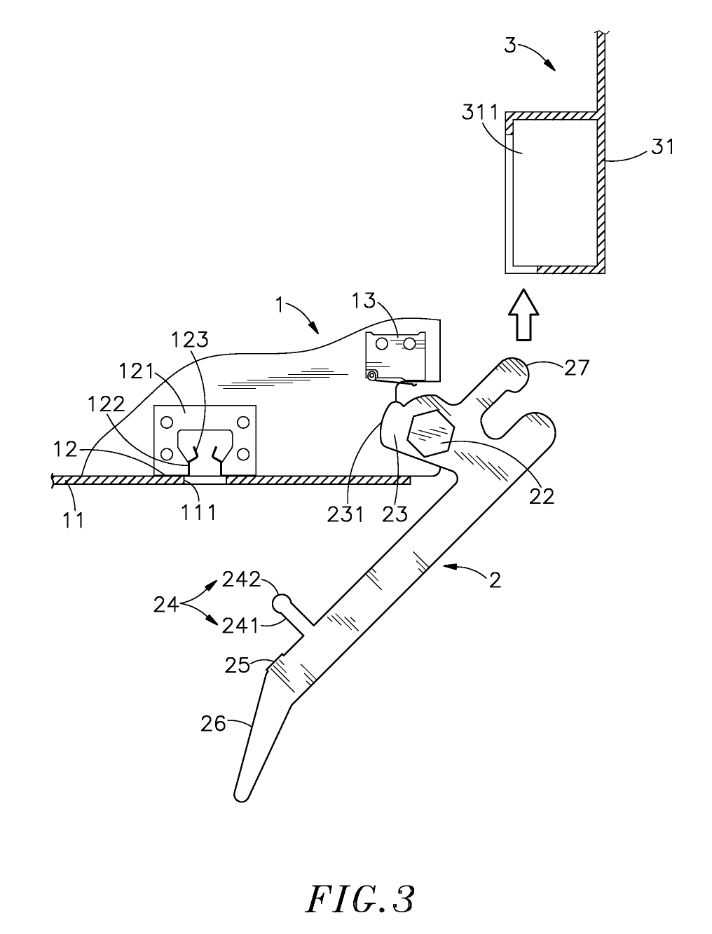

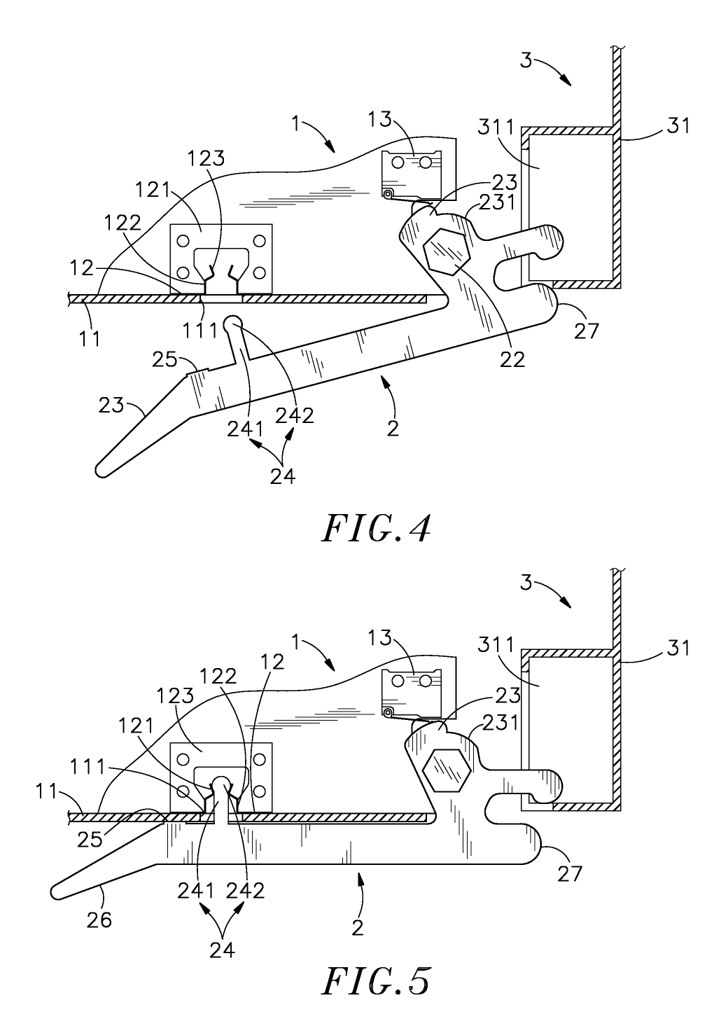

Referring to FIGS. 3˜7, after insertion of the motherboard blade 1 into a machine case 31 of a server system 3, turn the grip 26 of the locking lever 2 to force the locking rod 27 into engagement with a retaining hole 311 of the machine case 31 (i.e., turn the locking lever 2 from the unlocking position to the locking position). At this time, the actuating portion 23 touches the sensor switch 13, causing the sensor switches 13 to output a signal to the server system 3 indicative of accurate positioning of the motherboard blade 1 in the server system 3 so that the sever system 3 provides power supply to the motherboard blade 1. When engaging the locking rod 27 into the retaining hole 311 of the machine case 31 of the server system 3, the bearing portion 25 is stopped against the outside wall of the face panel 11, and the retaining member 24 is inserted into the through hole 111 and retained in place by the retaining spring arms 123 of the grounding plate 12. When inserting the retaining member 24 into the through hole 111, the head 242 forces the two retaining spring arms 123 apart. After the head 242 has been moved over the retaining spring arms 123, the spring power of the retaining spring arms 123 forces the retaining spring arms 123 to clamp on two opposite lateral sides of the neck 241, thereby securing the retaining member 24 positively to the grounding plate 12.

When turning the locking lever 2 relative to the motherboard blade 1 in the reversed direction from the locking position to the unlocking position, the locking rod 27 and the retaining member 24 are respectively disengaged from the machine case 31 and the grounding plate 12, and the actuating portion 23 is moved apart from the sensor switch 13, causing the sensor switch 13 to cut off power supply from the motherboard blade 1. Thus, the user can directly take the motherboard blade 1 out of the machine case 31 for a repair or maintenance work. Therefore, mounting and dismounting of the motherboard blade 1 are quite simple.

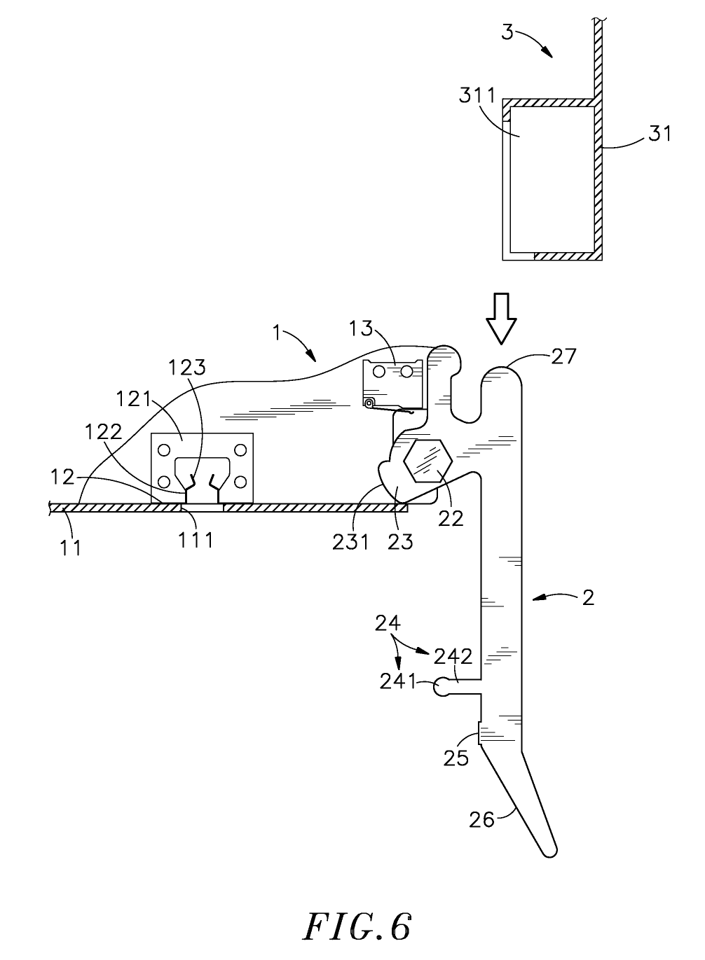

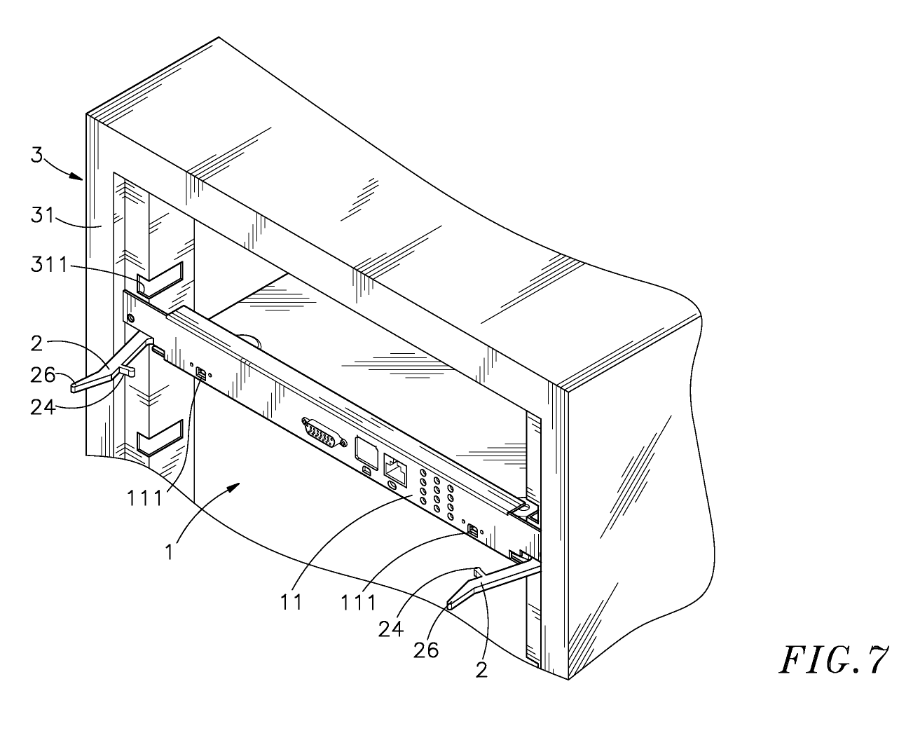

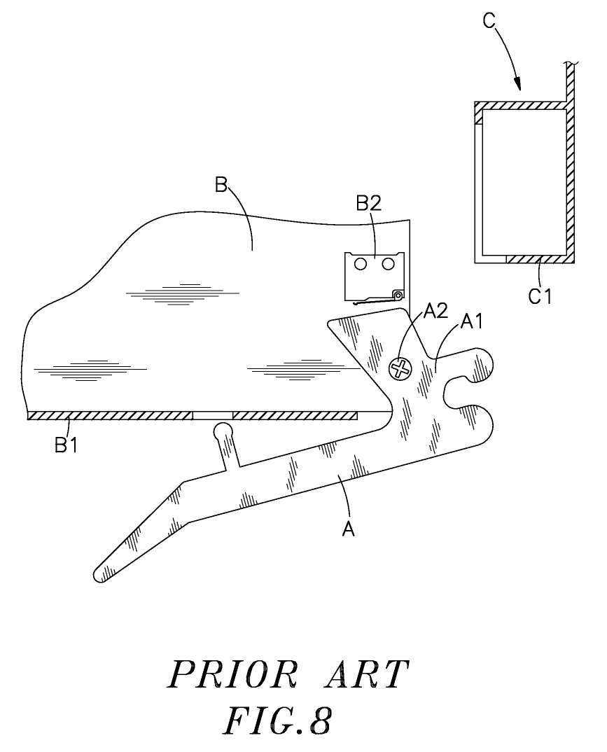

Further, the locking lever 2 is pivoted to the motherboard blade 1 in such a manner that the user can turn the locking lever 2 within 90-degrees between the locking position and the unlocking position. When the locking lever 2 is in the locking position, as shown in FIG. 5, the bearing portion 25 is stopped against the outside wall of the face panel 11 of the motherboard blade 1. On the contrary, when the locking lever 2 is in the unlocking position, as shown in FIG. 6, one end of the contact face 231 of the actuating portion 23 is stopped at the inside wall of the face panel 11 of the motherboard blade 1. Therefore, when turning the locking lever 2 between the locking position and the unlocking position, the locking rod 27 does not hit the sensor switch 23 accidentally.

In actual practice, as shown in FIG. 7, two locking levers 2 are used and provided at two sides of the motherboard blade 1 so that the locking levers 2 can positively lock the motherboard blade 1 to the machine case 31 of the server system 3.

The locking lever 2 is made out of metal in any of a variety of shapes. By means of engagement between the retaining member 24 and the retaining spring arms 123 of the grounding plate 12, the locking lever 2 guides static electricity and noises from the motherboard blade 1 to the machine case 31 for discharging to earth, i.e., the motherboard blade 1 is well grounded against interference of static electricity, noises and other magnetic waves.

As indicated above, the ATCA locking lever mounting arrangement of the present invention has the following features:

1. When turning the locking lever 2 from the unlocking position to the locking position, the retaining member 24 will be forced through the through hole 111 into engagement with the retaining spring arms 123 of the grounding plate 12, and the bearing portion 25 will be stopped at the outside wall of the face panel 11, holding the locking lever 1 positively in position.

2. The contact face 231 of the actuating portion 23 has a relatively smaller diameter than the actuating portion 23. Therefore, the locking lever 2 requires less space area around the sensor switch 13, and the surface area of the motherboard blade 1 can be fully utilized.

3. When turning the locking lever 2 from the locking position to the unlocking position, one end of the contact face 231 will be stopped at the inside wall of the face panel 11 to limit the turning angle of the locking lever 2, preventing the locking rod 27 from hitting the sensor switch 13 accidentally.

A prototype of ATCA locking lever mounting arrangement has been constructed with the features of FIGS. 1˜7. The locking lever and base frame board mounting arrangement for ATCA board functions smoothly to provide all of the features disclosed earlier.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. An ATCA locking lever mounting arrangement comprising:
a motherboard blade mounted in a machine case of a server system, said motherboard blade comprising a face panel at one side thereof, said face panel having a through hole, and a grounding plate disposed adjacent to said through hole of said face panel, said grounding plate having two retaining spring arms; and
a locking lever pivoted to said motherboard blade and adapted to lock said motherboard blade to said machine case of said server system, said locking lever having a lever body, said lever body having a first end and a second end remote from said first end, a pivot provided at said first end and pivoted to said motherboard blade, a retaining member protruded from one side of said lever body near said second end of said lever body and insertable into said through hole of said face panel for engagement by said retaining spring arms, and an actuating portion suspending around said pivot for triggering sensor means at said motherboard blade when said locking lever locks said motherboard blade to said machine base of said server system;
wherein said locking lever has a protruding bearing portion at one side of said second end of said lever body for stopping against an outside wall of said face panel to hold said locking lever in place when said retaining member is inserted through said through hole of said face panel into engagement with said retaining spring arms of said grounding plate.

2. The ATCA locking lever mounting arrangement as claimed in claim 1, wherein said locking lever has a grip extended from said second end of said lever body.

3. The ATCA locking lever mounting arrangement as claimed in claim 1, wherein said locking lever has a locking rod extended from said first end for engaging into a retaining hole of said machine case of said server system to lock said motherboard blade to said machine base of said server system.

4. The ATCA locking lever mounting arrangement as claimed in claim 1, wherein said retaining member of said locking lever has a head and a neck connected between said head and said lever body, said head having a transverse width greater than said neck.

5. The ATCA locking lever mounting arrangement as claimed in claim 1, wherein said actuating portion of said locking lever has a contact face for stopping at an inside wall of said face panel to limit the turning angle of said locking lever when said locking lever is turned outwards relative to said motherboard blade to disengage said locking rod from said machine case of said server system.
